(19) United States
(12) Patent Application Publication
(10) Pub. No.: US 2007/0215931 A1
(43) Pub. Date: Sep. 20, 2007

(54) Non-volatile memory cell in a trench having a first portion deeper than a second portion, an array of such memory cells, and method of manufacturing

(76) Inventors: Sohrab Kianian, Los Altos Hills, CA (US); Amitay Levi, Cupertino, CA (US)

Correspondence Address: DLA PIPER RUDNICK GRAY CARY US, LLP, 2000 UNIVERSITY AVENUE, E. PALO ALTO, CA, 94303-2248, US

(21) Appl. No.: 10/963,176

(22) Filed: Oct. 12, 2004

(51) Int. Cl. H01L 29/788

(52) U.S. Cl. 257/315

(57) ABSTRACT

A non-volatile memory cell is made in a substrate of a substantially single crystalline semiconductive material having a first conductivity type and a surface. A trench is in the surface and extends into the substrate to a first depth and to a second depth, which is deeper than the first depth. The trench has a first sidewall along the trench extending to the first depth, and a second sidewall along the trench extending from the first depth to the second depth, and a bottom wall along the bottom of the trench. A first region of a second conductivity type is in the substrate, along the bottom of the trench. A second region of the second conductivity type is in the substrate, along the surface of the trench. A channel region is in the substrate between the first region and the second region; the channel region has a first portion and a second portion, with the first portion between the surface and the first depth and is along the first sidewall. The second portion of the channel region is between the first depth and the second depth and is along the second sidewall. A control gate extends from the surface of the substrate into the trench to the second depth, insulated from the bottom. The control gate is adjacent to and insulated from the second sidewall of the trench. A floating gate is adjacent to and insulated from the first sidewall of the trench, between the first sidewall of the trench and the control gate.

### TECHNICAL FIELD

The present invention relates to a nonvolatile floating gate memory cell made in a trench of a semiconductor substrate, with the trench having a first portion deeper than a second portion, an array of such cells, and a method of manufacturing.

### BACKGROUND OF THE INVENTION

Nonvolatile memory cells with each having a floating gate for the storage of charges thereon to control the conduction of current in a channel in a substrate of a semiconductive material is well-known in the art. Typically, such cells have been made in a semiconductor material which has a substantially flat surface along a horizontal plane. However, the prior art also discloses manufacturing such cells in a vertical relationship in a pillar which are gaps in a vertical position See, for example, U.S. Pat. No. 6,633,057; 6,235,583; 6,157,061; 5,999,453; 5,616,511; and 5,567,637. In addition, see the article entitled “A Self-Aligned Split-Gate Flash EEPROM Cell With 3-D Pillar Structure” by Fumihiko Hayashi and James D. Plummer published in the 1999 Symposium on VLSI Technology Digest of Technical Papers pages 87 and 88. The Hayashi and Plummer paper discloses a memory cell in which a channel silicon pillar is surrounded by a floating gate and a control gate.

In the prior art, non-volatile memory cells using floating gates for the storage of charges thereon have been either of the stack gate type or of a split gate type. In a stack gate type, the control gate is aligned with the floating gate and controls the entire channel region of the memory cell. In a split gate type, the control gate has at least a portion adjacent to the floating gate and controls a portion of the channel region while the floating gate controls another portion of the channel region.

Heretofore, none of the references discloses formation of a split gate type non-volatile memory cell wherein the cell is made in a trench having a first portion deeper than a second portion.

It is therefore, an object of the present invention to overcome this and other difficulties.

### SUMMARY OF THE INVENTION

Accordingly, in the present invention, a non-volatile memory cell comprises a substrate of a substantially single crystalline semiconductive material having a first connectivity type with a surface. A trench is located in the surface and extends into the substrate to a first depth and to a second depth which is deeper than the first depth. The trench has a first side wall along the trench and extends to the first depth and a second sidewall along the trench extending from the first depth to the second depth and a bottom. A first region of a second conductivity type is in the substrate along the bottom of the trench. A second region of the second conductivity type is in the substrate along the surface of the trench. A channel region is formed in the substrate between the first region and the second region with the channel region having a first portion and a second portion. The first portion of the channel region is between the surface and the first depth and is along the first sidewall. The second portion of the channel region is between the first depth and the second depth and is along the second sidewall. A control gate extends from the surface of the substrate into the trench to the second depth insulated from the bottom. The control gate is adjacent to and insulated from the second sidewall of the trench. A floating gate is adjacent and insulated from the first sidewall of the trench between the first portion of the channel region and the control gate.

The present invention also relates to an array of the foregoing described nonvolatile memory cells. Finally, the present invention relates to a method of manufacturing an array of nonvolatile memory cells.

### BRIEF DESCRIPTION OF THE DRAWINGS

FIGS. 1A-1K are cross-sectional views showing a method of forming the non-volatile memory cell and array of the present invention with the cross-sectional view taken along the lines A-A shown in FIG. 2

FIGS. 1L-1N are cross-sectional views of a method of forming the non-volatile memory array of the present invention with the cross-sectional view taken along the lines B-B shown in FIG. 2.

FIG. 2 is a top view of the array of nonvolatile memory cells of the present invention.

### DETAILED DESCRIPTION OF THE INVENTION

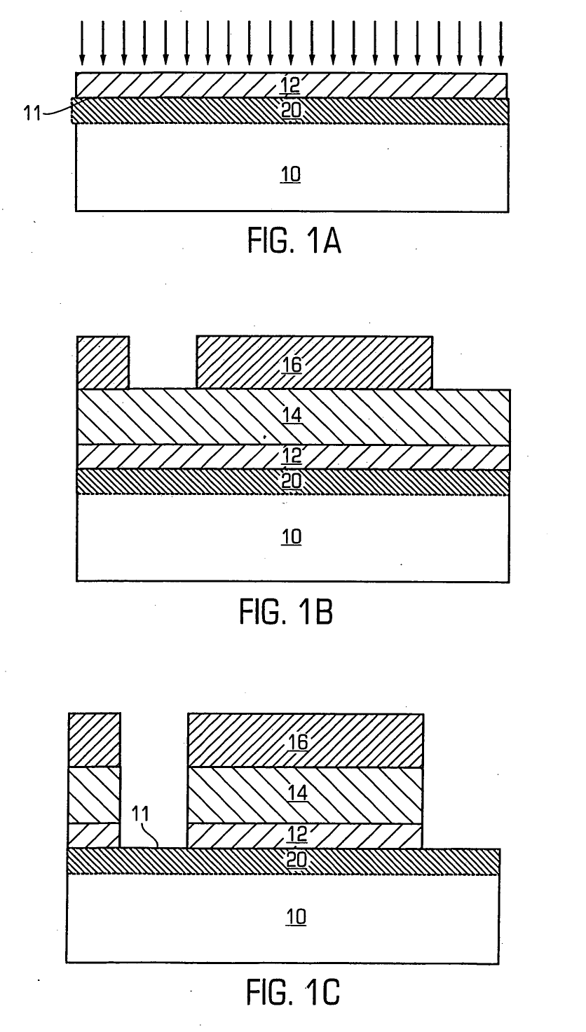

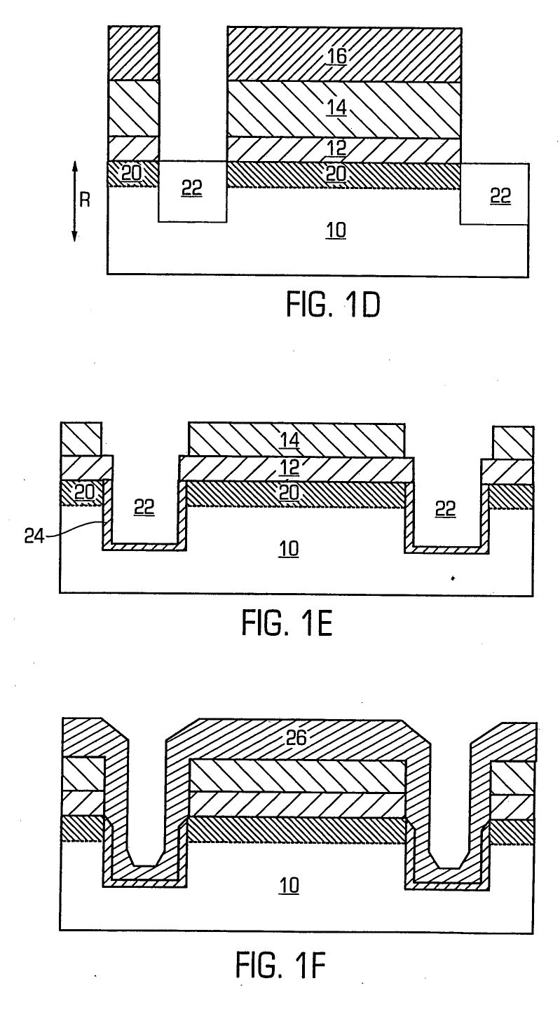

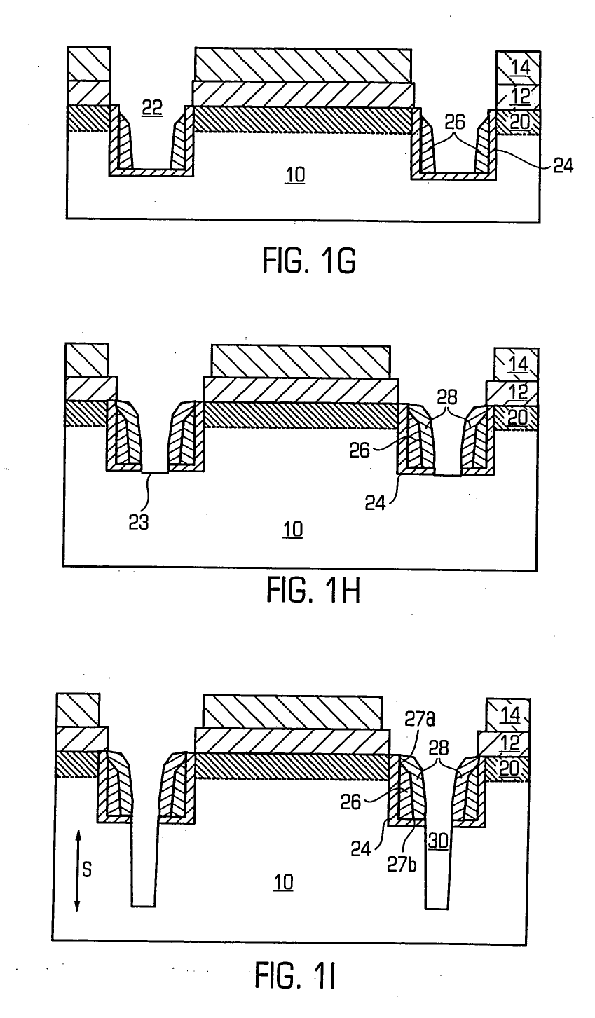

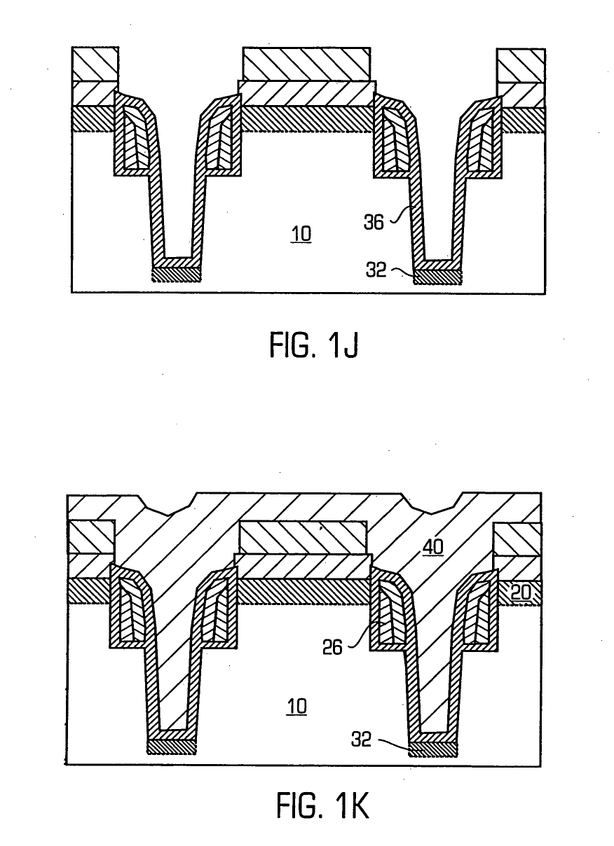

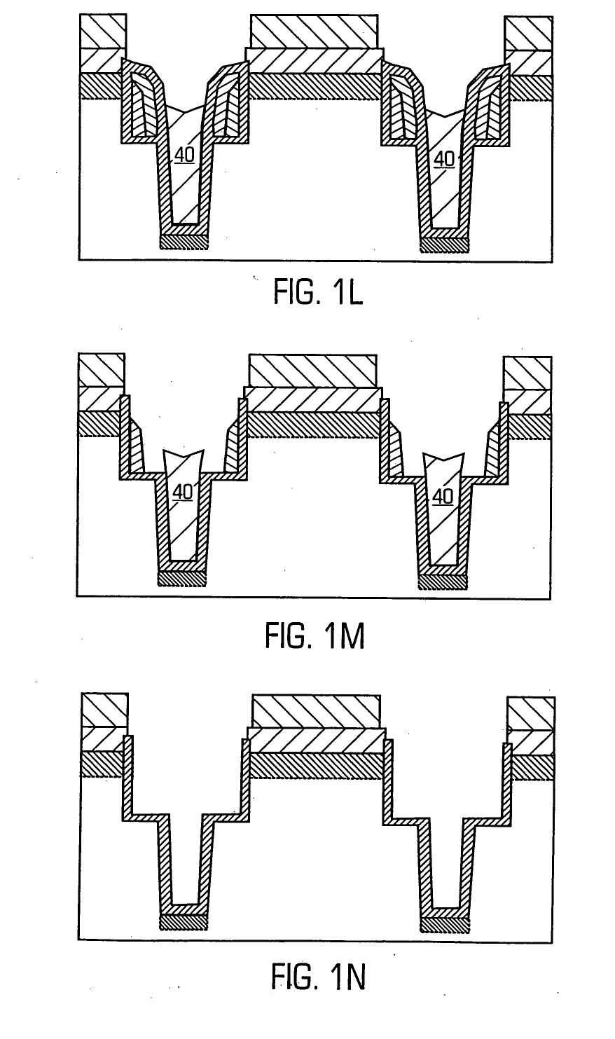

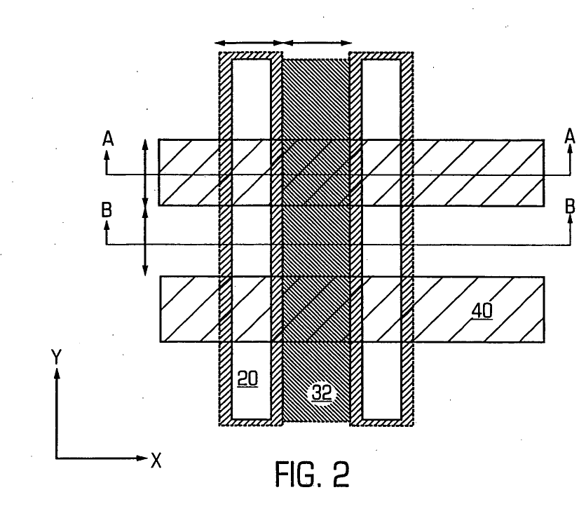

Referring to FIG. 1A, there is shown a cross-sectional view of a first step in the manufacture of the nonvolatile memory cell and array of the present invention. A cross-sectional view of the finished nonvolatile memory cell and array of the present invention is shown in FIG. 1K with a top view of an array of such nonvolatile memory cells shown in FIG. 2.

In the first step of the method of the present invention in forming the nonvolatile memory cell and array of the present invention, a substantially single crystalline semiconductor substrate 10, such as silicon is shown. The substrate 10 is of a first conductivity type, preferably P-type. It has a horizontal surface 11. A first layer of silicon oxide or silicon dioxide 12 is deposited on the surface 11. Typically, the layer of silicon dioxide 12 is formed by thermal oxidation or deposited oxide, resulting in a layer of approximately 200 angstroms in thickness. It should be noted that the present process described herein is for the 90 nm process. However, the invention is not so limited and for different scale of integration, different dimensions need to be used. After the silicon dioxide layer 12 is formed, an implantation or multiple implantations are made through the silicon dioxide layer 12 and into the substrate 10. This results in the formation of a N-type region 20 beneath the entire surface 11 of the substrate 10. The resulting structure is shown in FIG. 1A.

A layer of silicon nitride 14 is deposited on the layer of silicon dioxide 12. The silicon nitride 14 can be formed by Chemical Vapor Deposition (CVD) resulting in a thickness of 500 angstroms thick silicon nitride 14. A photoresist layer 16 is then deposited on the layer of silicon nitride 14. The photoresist material 16 is masked and portions are cut from the photoresist material 16. The resulting structure is shown in FIG. 1B.

The openings in the photoresist 16 is used. as a mask to cut (i.e. anisotropically etch) through the silicon nitride 14 and through the silicon dioxide 12 onto the substrate 10. The resulting structure is shown in FIG. 1C.

With the surface 11 of the substrate 10 exposed, the substrate 10 is anisotropically etched forming trenches 22. The trenches 22 are etched to a first depth R of approximately 90 nanometers. The resulting structure is shown in FIG. 1D.

The photoresist material 16 is then removed. An optional, disposable, liner oxide layer can be formed and removed before the high quality gate oxide is formed by exposing the structure to an oxidation atmosphere to oxidize the exposed silicon in trenches 22 in the substrate 10. The exposure which oxidizes the exposed silicon substrate 10 results in the formation of a layer 24 of silicon dioxide of approximately 80 angstroms. This can be done by thermal oxidation. The resulting structure is shown in FIG. 1E.

Polysilicon 26 is then deposited on the structure shown in FIG. 1E. The polysilicon is deposited everywhere on the silicon nitride 14 and in the trenches 22 along the side wall and the bottom wall thereof. The polysilicon 26 can be a layer of 300 angstroms thick. The resulting structure is shown in FIG. 1F.

The structure in FIG. 1F is then anisotropically etched resulting in the formation of polysilicon spacers in each of the trenches 22 along the sidewalls thereof and spaced apart from one another along the bottom of the trench 22. The resulting structure is shown in FIG. 1G. The formation of the polysiklicon spacer 26 results in a tip 27a near the top of the trench 22. In addition, by adding an isotropic etch component, a tip 27b can also be formed at the bottom of the trench 22. Furthermore, other well know methods of oxidation of the polysilicon spacer 26 can enhance the tip 27 (a or b) at either the top or at the bottom of the trench 22.

Another layer of silicon dioxide 28 is then deposited on the structure shown in FIG. 1G covering the silicon nitride 14 and into the trenches 22 covering the polysilicon spacer 26 and along the bottom of the trenches 22. The layer of silicon dioxide 28 is approximately 300 angstroms thick. This can be done by CVD deposition. The layer of silicon dioxide 28 is then anisotropically etched forming silicon dioxide spacers 28 which cover the polysilicon spacers 26 but are also spaced apart from one another along the bottom wall of each of the trenches 22, forming an opening 23. The opening 23 formed on the bottom of the trench 22 is on the order of 70 nanometers. Because of the anisotropically etching of the silicon dioxide 28 to form the spacers, the silicon dioxide 24 which was along the bottom of each of the trenches but between the silicon dioxide spaces 28, is also etched. Thus, each of the openings 23 directly exposes the silicon substrate 10 along the bottom wall of each of the trenches 22. The resulting structure is shown in FIG. 1H.

Using the silicon dioxide spacers 28 as a mask, in each of the trenches 22, and with the silicon nitride 14 covering the surface 11 of the substrate 10, the structure shown in FIG. 1H is subject to an anisotropic silicon etch which cuts further into each of the trenches 22 to a second depth S. The second depth S is deeper than the first depth R. The second depth S extends from the bottom wall of the first trench 22 to a level 90 nanometers below the first depth R. The resulting structure is shown in FIG. 1I.

Another layer of silicon dioxide 36 is then deposited on the structure shown in FIG. 1I. This covers the silicon nitride 14 along the surface, and along the silicon dioxide spacers 28 and along the sidewall and bottom wall of the second trench 30. The thickness of the silicon dioxide layer 36 is approximately 120 angstroms and would eventually form the gate oxide region for the control gate. After the silicon dioxide layer 36 is formed, ion implantation is performed into the structure forming the second region 32 of N type conductivity 32 which is along the bottom wall of the second trench 30. The resulting structure is shown in FIG. 1J.

Polysilicon 40 is then deposited everywhere and covers the entire structure shown in FIG. 1J including into the first trenches 22 and into the second trenches 30 formed therein. The polysilicon 40 is insulated from the substrate 10 by the silicon dioxide layer 36. The resulting structure is shown in FIG. 1K. The structure shown in FIG. 1K is a cross-sectional view of a finished non-volatile memory cell and is taken in a cross-sectional direction shown in FIG. 2 along the lines A-A. Although each of the cells shown in the x direction or in the row direction are completed, they are also connected to one another in the y direction. Thus, a further processing step is needed to “disconnect” each of the rows from one another in the Y direction. This is accomplished by the processing steps described hereinafter and as shown and explained in FIGS. 1L through 1N.

Referring to FIG. 1L, there is shown a cross-sectional view taken along the line B-B shown in FIG. 2. The polysilicon 40 is then masked and is cut in the Y direction. The polysilicon 40 is etched anisotropically until the silicon nitride 14. The resulting structure is shown in FIG. 1 L wherein the polysilicon 40 is partially removed from the trenches 22 and second trenches 30.

The structure shown in FIG. 1L is then subject to an anisotropic silicon dioxide etch removing the portion of the silicon dioxide layer 36 which is exposed as well as the silicon dioxide spacer 28. The resulting structure is shown in FIG. 1M.

The structure shown in FIG. 1M is then subject to an anisotropic polysilicon etch until the polysilicon 40 remaining in the trenches 22 and the second trenches 30 as well as the polysilicon spacer 26 remaining in the trench 22 are removed. The resulting structure is shown in FIG. 1N. The “void” in the trenches 22 and second trenches 30 shown in FIG. 1N may then be filled with an insulating material thereby breaking the continuity in the cells in the row direction. The resulting structure is an array of nonvolatile memory cells.

The operation of the cell and memory array of the present invention is as follows.

To program a selected cell, the selected control gate polysilicon 40 receives approximately 1.2 volt, the selected common source region 20 receives approximately 7 volts, and the selected drain region 32 receives approximately 0.5 volt. This turns on the control gate channel region, in the portion of the trench which is deeper. The electrons traverse the channel region from the drain region 32 to the source region 20, and are injected onto the floating gate 26. The unselected drain regions 32 are supplied with a voltage higher than the voltage applied to the selected control gate polysilicon 40 in order to turn off the associated unselected channels and to prevent electrons from traversing from the unselected drain region 32 to the selected source region 20. This can be on the order of 1.5 volts. All other unselected source regions 20 are left floating or at ground.

To erase a selected cell, the selected control gate polysilicon 40 receives approximately 10 volts, and all other nodes are at ground. The electrons on the floating gate 26 tunnel from the floating gate 26 onto the control gate polysilicon 40. Since erase is by sector, all the cells in the same row having the same control gate polysilicon 40 are erased simultaneously.

To read a selected cell, the selected control gate polysilicon 40 receives close to full supply voltage (approximately 1 volt), the common source region 20 is grounded and the selected drain region 32 receives approximately 1 volt. Electrons would flow from the common source region 20 to the selected drain region 32 if the floating gate 26 were not programmed with electrons. If the floating gate 26 is programmed with electrons, then current would not flow in that selected cell. The unselected drain regions 32 is held at ground. Thus, for the unselected cells, no current can flow between the unselected drain region 32 and the unselected source region 20. All other unselected source regions 20 are also at ground.

What is claimed is:

1. A non-volatile memory cell comprising:
a substrate of a substantially single crystalline semiconductive material having a first conductivity type and having a surface;
a trench in said surface extending into said substrate to a first depth and to a second depth, deeper than said first depth; said trench having a first sidewall along said trench extending to said first depth, and a second sidewall along said trench extending from said first depth to said second depth, and a bottom wall along the bottom of said trench,
a first region of a second conductivity type in said substrate, along said bottom of said trench;
a second region of said second conductivity type in said substrate, along said surface of said trench;
a channel region in said substrate between said first region and said second region, said channel region having a first portion and a second portion, wherein said first portion is between said surface and said first depth and is along said first sidewall, and wherein said second portion is between said first depth and said second depth and is along said second sidewall;
a control gate extending from said surface of said substrate into said trench to said second depth, insulated from said bottom; said control gate adjacent to and insulated from said second sidewall of said trench;
a floating gate adjacent to and insulated from said first sidewall of said trench, between said first portion of said trench region and said control gate.

2. The cell of claim 1 wherein said substrate is single crystalline silicon.

3. The cell of claim 2 wherein said surface is substantially planar.

4. The cell of claim 3 wherein said floating gate further comprising a tip near said first depth, directed at said control gate, and wherein said tip is insulated from said control gate by a first insulating material.

5. The cell of claim 4 wherein said first insulating material permits Fowler-Nordheim tunneling of charges from said tip to said control gate.

6. The cell of claim 5 wherein said control gate is insulated from said second portion of said channel region by a first layer of silicon dioxide.

7. The cell of claim 6 wherein said floating gate is insulated from said first portion of said channel region by a second layer of silicon dioxide, and is insulated from said control gate by a third layer of silicon dioxide.

8. An array of non-volatile memory cells comprising:
a substrate of a substantially single crystalline semiconductive material having a first conductivity type and having a surface;
a plurality of spaced apart trenches, substantially parallel to one another, extending in a first direction, each of said trenches extending from said surface into said substrate to a first depth and to a second depth, deeper than said first depth; each of said trenches having a first sidewall extending to said first depth, and a second sidewall extending from said first depth to said second depth, and a bottom wall,
a first region of a second conductivity type in said substrate, along said bottom wall of each of said trenches, extending in said first direction;
a second region of said second conductivity type in said substrate, along said surface of said trench, between each pair of adjacent trenches, and extending in said first direction;
a channel region in said substrate between said first region and said second region of each trench, said channel region having a first portion and a second portion, wherein said first portion is between said surface and said first depth and is along said first sidewall, and wherein said second portion is between said first depth and said second depth and is along said second sidewall;
a plurality of spaced apart control gates, each control gate extending in a second direction, substantially perpendicular to said first direction, with each control gate extending from said surface of said substrate into said trench to said second depth, insulated from said bottom wall; said control gate adjacent to and insulated from said second portion of said channel region; and
a plurality of floating gates, each floating gate adjacent to and insulated from said first portion of each channel region, between said first portion and a control gate.

9. The array of claim 8 wherein said substrate is single crystalline silicon.

10. The array of claim 9 wherein said surface is substantially planar.

11. The array of claim 10 wherein said floating gate further comprising a tip near said first depth, directed at said control gate, and wherein said tip is insulated from said control gate by a first insulating material.

12. The array of claim 11 wherein said first insulating material permits Fowler-Nordheim tunneling of charges from said tip to said control gate.

13. The array of claim 12 wherein said control gate is insulated from said second portion of said- channel by a first layer of silicon dioxide.

14. The array of claim 13 wherein said floating gate is insulated from said first portion of said channel by a second layer of silicon dioxide, and is insulated from said control gate by a third layer of silicon dioxide.

15. The array of claim 8 further comprising an insulating material between each control gate extending in said second direction and filling each of said trenches.

16. A method of making an array of non-volatile memory cells in a semiconductor substrate of a first conductivity having a planar surface, of a first conductivity type, said method comprising:
forming a first region of a second conductivity type along said planar surface;
forming a plurality of spaced apart trenches extending in said first direction, each trench extending from the planar surface into the substrate to a first depth, and having a first sidewall and a first bottom wall;
forming a plurality of floating gates, each floating gate adjacent to and insulated from each first sidewall and spaced apart from one another along said first bottom wall, in each trench,
extending each trench to a second depth deeper than said first depth from said first bottom wall between a pair of floating gates in each trench, thereby forming a second trench having a second sidewall between said first depth and said second depth and reaching a second bottom wall;
forming a second region of a second conductivity type in said substrate along said second bottom wall, each second region extending in said first direction;
forming a word line extending in said second direction, substantially perpendicular to said first direction and into each trench extending to said second bottom wall; said word line adjacent to and insulated from said second sidewall and said bottom wall; and adjacent to and insulated from each floating gate;
masking said word line to form a plurality of spaced apart word lines, each word line extending in a second direction, substantially perpendicular to said first direction, with a cut region between each pair of adjacent spaced apart word lines;
removing said floating gate from each of said cut regions in said trench extending to said first depth;
removing said control gate from each of said cut regions in said trench extending to said second depth; and
filling each of said cut regions with an insulating material.

17. The method of claim 16 wherein said step of forming a plurality of spaced apart trenches further comprising:
forming a spacer of polysilicon adjacent to said first sidewall.

18. The method of claim 16 wherein said step of forming a plurality of spaced apart trenches also forms a plurality of spaced apart first regions, each extending in said first direction along said planar surface.
